(19) United States
(12) Patent Application Publication
(10) Pub. No.: US 2010/0244281 A1
(43) Pub. Date: Sep. 30, 2010

(54) FLEXIBLE PRINTED WIRING BOARD AND SEMICONDUCTOR DEVICE EMPLOYING THE SAME

(75) Inventors: Katsuhiko HAYASHI, Ageo-shi (JP); Tatsuo KATAOKA, Ageo-shi (JP)

Correspondence Address: SUGHRUE MION, PLLC, 2100 PENNSYLVANIA AVENUE, N.W., SUITE 800, WASHINGTON, DC, 20037, US

(73) Assignee: MITSUI MINING & SMELTING CO., LTD., Tokyo (JP)

(21) Appl. No.: 12/750,597

(22) Filed: Mar. 30, 2010

(30) Foreign Application Priority Data
Mar. 31, 2009 (JP) 2009-087032

(51) Int. Cl. H01L 23/498; H05K 1/16; H05K 1/00

(52) U.S. Cl. 257/784; 174/260; 174/254; 257/E23.065

(57) ABSTRACT

Objects of the present invention is to provide a flexible printed wiring board which has a simple structure, which can be produced at low cost, and which can effectively dissipate heat generated by semiconductor chips, and to provide a semiconductor device employing the flexible printed wiring board. The flexible printed wiring board of the invention has an insulating substrate, and a wiring pattern formed of a conductor layer and provided on one surface of the insulating substrate, wherein the wiring pattern includes inner leads for mounting a semiconductor chip and outer leads for input and output wire connection, and a metal layer is adhered to the wiring pattern via an insulating adhesion layer.

The entire disclosure of Japanese Patent Application No. 2009-087032 filed Mar. 31, 2009 is expressly incorporated by reference herein.

### BACKGROUND OF THE INVENTION

1. Field of the Invention

The present invention relates to a flexible printed wiring board having excellent heat dissipation properties, and to a semiconductor device employing the wiring board.

2. Background Art

Printed wiring boards such as FPCs (flexible printed circuits) and film carrier tapes for TCP (tape carrier package, having device holes) and for COF (chip on film, having no device hole) are employed in, for example, liquid-crystal televisions and organic EL televisions, and driver IC chips for driving the devices or other elements are mounted thereon. One problem in such devices is heat generated by IC chips.

Meanwhile, in a trend for producing fine-pitch wiring patterns in printed wiring boards, the width and thickness of a conductor wire has decreased. This impairs the efficiency of heat dissipation from wiring patterns. Thus, attempts have been made to provide printed wiring boards with a structure which allows heat from high-temperature mounted devices to effectively dissipate.

One proposed structure is a printed wiring board having on its back side heat-dissipating means (see, for example, Japanese Patent Application Laid-Open (kokai) No. 2001-284748). However, the structure has some problems. That is, when heat-dissipating means such as a metal sheet is laminated on the back surface of the wiring board, transparency of the substrate is reduced, making it difficult to position a pattern carried out in a bonding step of mounting a part on an inner lead. In addition, since the heat of a bonding tool is dissipated through the heat-dissipating means attached to the back side, bonding temperature must be elevated.

Japanese Patent Application Laid-Open (kokai) No. 1995-235737 discloses a structure in which a heat-dissipating sheet is provided to cover an opening perforated in a base substrate, and an IC chip is mounted on the heat-dissipating sheet. However, the structure has also problems. That is, the structure is produced from a metal substrate through a process including a number of steps such as light exposure, development, and etching, and the space required for provision of the heat-dissipating sheet causes an increase in wiring area.

Japanese Patent Application Laid-Open (kokai) No. 2007-258197 discloses a structure in which copper foil is formed on a wiring layer by the mediation of an adhesive for copper foil. However, the disclosed structure also has a problem. That is, since a semiconductor chip is mounted on the back side of a polyimide tape substrate having device holes, heat of the semiconductor chip is not satisfactorily dissipated, although heat of wiring patterns may be satisfactorily dissipated.

### SUMMARY OF THE INVENTION

In view of the foregoing, an object of the present invention is to provide a flexible printed wiring board which has a simple structure, which can be produced at low cost, and which can dissipate heat generated by semiconductor chips. Another object of the invention is to provide a semiconductor device employing the flexible printed wiring board.

In a first mode of the present invention for attaining the aforementioned objects, there is provided a flexible printed wiring board comprising:

an insulating substrate,

a wiring pattern formed of a conductor layer and provided on one surface of the insulating substrate,

an insulating adhesion layer, and

a metal layer,

wherein the wiring pattern includes inner leads for mounting a semiconductor chip and outer leads for input and output wire connection, and the metal layer is adhered to the wiring pattern via the insulating adhesion layer.

According to the first mode, by virtue of a simple structure in which the metal layer is adhered to the wiring pattern via the insulating adhesion layer, heat generated by the wiring pattern and the mounted semiconductor chip can be effectively dissipated via the metal layer.

A second mode of the present invention is directed to a specific embodiment of the flexible printed wiring board of the first mode, wherein the insulating adhesion layer covers areas except for any of the inner leads and the outer leads, and the metal layer is provided in the vicinity of a semiconductor chip mounted on the inner leads.

According to the second mode, the metal layer is provided in the vicinity of a semiconductor chip mounted on the inner leads. Therefore, heat radiated by the semiconductor chip is effectively dissipated via the metal layer.

A third mode of the present invention is directed to a specific embodiment of the flexible printed wiring board of the second mode, wherein the metal layer has an edge on the inner lead side which edge recedes from an edge on the inner lead side of the insulating adhesion layer, and the edge of the insulating adhesion layer protrudes from the edge of the metal layer.

According to the third mode, the insulating adhesion layer protrudes on the inner lead side. Therefore, when a semiconductor chip is mounted on the inner leads, an exposed portion of each inner lead is covered with the insulating adhesion layer, whereby durability of the inner lead can be enhanced.

A fourth mode of the present invention is directed to a specific embodiment of the flexible printed wiring board of the first mode, wherein the insulating adhesion layer covers the inner leads, an area of the substrate between edges of the opposing inner leads, and an area of the wiring pattern other than the outer leads, and the metal layer is provided on an area of the insulating adhesion layer other than any of an area thereof on the inner leads and an area thereof between the edges of the opposing inner leads.

According to the fourth mode, a semiconductor chip is mounted on the inner leads covered with the insulating adhesion layer. The portion of the insulating adhesion layer between the edges of the opposing inner leads serves as an under-filling material for the semiconductor chip.

A fifth mode of the present invention is directed to a specific embodiment of the flexible printed wiring board of any one of the second to fourth modes, wherein the metal layer has an edge on the outer lead side which edge recedes from an edge on the outer lead side of the insulating adhesion layer, and the edge of the insulating adhesion layer protrudes from the edge of the metal layer, to thereby cover a part of a connection terminal of each outer lead.

According to the fifth mode, when an output or input member is connected to the output outer lead or input outer lead via ACF or the like, ACF covers a corresponding edge of the insulating adhesion layer. Thus, an exposed portion of the outer lead is covered, to thereby enhance durability of the outer lead.

A sixth mode of the present invention is directed to a specific embodiment of the flexible printed wiring board of any one of the first to fifth modes, wherein the insulating adhesion layer is formed of NCF or NCP.

According to the sixth mode, insulation and adhesion between the wiring pattern and the metal layer is ensured by an insulating adhesive made of NCF or NCP.

A seventh mode of the present invention is directed to a specific embodiment of the flexible printed wiring board of any one of the first to sixth modes, wherein the insulating adhesion layer contains a thermosetting resin in a semi-cured state.

According to the seventh mode, an insulating adhesive formed of thermosetting resin is used. Thus, mounted semiconductor chips have high stability to heat and high reliability, as compared with the case where an insulating adhesive formed of thermoplastic resin is used.

An eighth mode of the present invention is directed to a specific embodiment of the flexible printed wiring board of any one of the first to seventh modes, which has no solder resist layer on the wiring pattern.

According to the eighth mode, no solder resist layer is used, but the insulating adhesion layer serves also as a solder resist layer, whereby production cost can be reduced.

In a ninth mode of the present invention, there is provided a semiconductor device comprising a semiconductor chip mounted on the inner leads of a flexible printed wiring board as recited in any one of the first to eighth modes, and input and output members connected to the outer leads.

According to the ninth mode, the heat generated by the semiconductor chip mounted on the inner leads is effectively dissipated via the metal layer, and reliable operation is realized.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1A is a schematic plan view of a flexible printed wiring board according to Embodiment 1 of the present invention;

FIG. 1B is a cross-sectional view of a flexible printed wiring board according to Embodiment 1 of the present invention;

FIG. 2 is a schematic cross-sectional view of a semiconductor device employing the flexible printed wiring board according to Embodiment 1 of the present invention;

FIG. 3A is a schematic plan view of a flexible printed wiring board according to Embodiment 2 of the present invention;

FIG. 3B is a cross-sectional view of a flexible printed wiring board according to Embodiment 2 of the present invention;

FIG. 4 is a schematic cross-sectional view of a semiconductor device employing the flexible printed wiring board according to Embodiment 2 of the present invention;

FIG. 5A is a schematic plan view of a flexible printed wiring board according to Embodiment 3 of the present invention;

FIG. 5B is a cross-sectional view of a flexible printed wiring board according to Embodiment 3 of the present invention;

FIG. 6 is a schematic cross-sectional view of a semiconductor device employing the flexible printed wiring board according to Embodiment 3 of the present invention;

FIG. 7A is a schematic plan view of a flexible printed wiring board according to Embodiment 4 of the present invention;

FIG. 7B is a cross-sectional view of a flexible printed wiring board according to Embodiment 4 of the present invention; and

FIG. 8 is a schematic cross-sectional view of a semiconductor device employing the flexible printed wiring board according to Embodiment 4 of the present invention.

### DETAILED DESCRIPTION OF PREFERRED EMBODIMENTS

Embodiments of the flexible printed wiring board according to the present invention and embodiments of the semiconductor device employing the flexible printed wiring board according to the present invention will next be described.

### Embodiment 1

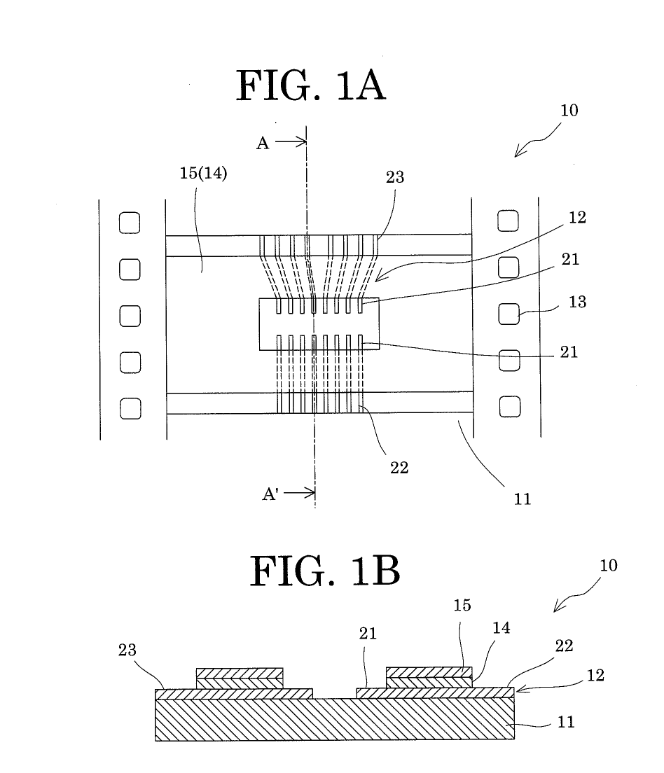

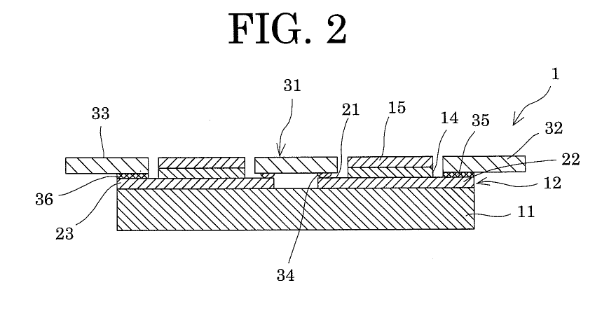

FIG. 1A is a schematic plan view of a flexible printed wiring board according to Embodiment 1 of the present invention; FIG. 1B is a cross-sectional view of the same; and FIG. 2 is a schematic cross-sectional view of a semiconductor device employing the flexible printed wiring board on which semiconductor chips and other parts have been mounted.

FIG. 1A shows a flexible printed wiring board 10 according to Embodiment 1, which is a film carrier tape having a flexible insulating substrate 11, and a wiring pattern 12 formed through patterning a conductor layer formed on one surface of the insulating substrate 11. The film carrier tape has, along each longitudinal edge thereof, a row of sprocket holes 13 (constant pitch) for conveyance, and a metal layer 15 is provided on the wiring pattern 12 via an insulating adhesion layer 14.

The insulating layer 11 may be formed from a material having flexibility as well as resistance to heat and chemicals. Examples of the material of the insulating substrate 11 include polyester, polyamide, and polyimide. Among them, an aromatic polyimide (all repeating units being aromatic) having a biphenyl skeleton (e.g., Upilex, product of Ube Industries, Ltd.) is particularly preferred. The thickness of the insulating layer 11 is generally 25 to 125 μm.

The wiring pattern 12 is formed on one surface of the insulating substrate 11 provided with sprocket holes 13 and other parts. Generally, the wiring pattern has a base layer and a plate layer which is formed on at least a part of the base layer. The base layer is formed through patterning a conductor layer made of conductor foil (copper or aluminum foil). In FIGS. 1A and 1B, and the description hereinafter, the presence of the plate layer is omitted.

Such a conductor layer providing the wiring pattern 12 may be directly laminated on the insulating substrate 11, or formed via an adhesive layer through hot press-bonding or another means. In an alternative mode, differing provision of conductor foil on the insulating substrate 11, a polyimide precursor or the like is applied onto conductor foil, followed by firing, whereby the insulating substrate 11 made of polyimide film can be produced. The wiring pattern 12 generally has a thickness of 5 to 20 μm.

The wiring pattern 12 made of the conductor layer and provided on the insulating substrate 11 is generally patterned through photolithography. Specifically, a photoresist is applied onto the substrate, the photoresist layer is removed through chemically dissolving (etching) it with an etchant via a photomask, and the remaining photoresist layer is removed through dissolving it with an alkali or the like, to thereby pattern the conductor foil, whereby the wiring pattern 12 is formed. As mentioned hereinbelow, the wiring pattern 12 includes inner leads 21 for mounting semiconductor chips, input outer leads 22 to which an input member such as a substrate is connected, and output outer leads 23 to which an output member such as an LCD panel is connected.

No particular limitation is imposed on the material of the insulating adhesion layer 14, so long as it is an adhesive having electrical insulating property. For example, NCF (non conductive film) and NCP (non conductive paste) may be used. NCF and NCP have advantageous properties such as high-adhesion-strength, softness, halogen-free, and low-warpage. Thus, these properties are preferred, for serving as an alternative material for a solder resist layer.

The insulating adhesion layer 14 preferably has thermal conductivity in order to dissipate heat generated from the wiring pattern 12 via the metal layer 15. However, the thermal conductivity is not essential for the following reason. Specifically, in the present invention, radiant heat generated from semiconductor chips is dissipated mainly via the metal layer 15, and the insulating adhesion layer 14 does not necessarily have thermal conductivity.

In the case where the insulating adhesion layer 14 is formed from, for example, NCF or NCP, the layer contains thermoplastic resin or thermosetting resin. Form the viewpoint of thermal stability of mounted semiconductor chips, the insulating adhesion layer preferably contains thermosetting resin. When the insulating adhesion layer 14 contains thermosetting resin, and the layer is present in a film carrier tape before mounting semiconductor chips, preferably, the layer is in a semi-cured state and thermally cured after mounting semiconductor chips.

In the case where the insulating adhesion layer 14 is employed as an under-filling material for semiconductor chips, the adhesion layer is preferably formed from thermoplastic resin, since thermoplastic resin is softened and melted during a thermal press-bonding step for mounting semiconductor chips and sufficiently enters a wiring portion under a semiconductor chip and a portion around the semiconductor chip. However, a thermosetting material such as NCF is also preferred, when the thermosetting material is laminated in a semi-cured state by heating at, for example, about 80° C., to thereby form a flexible printed wiring board. In this mode, when thermal press-bonding is performed (e.g., at 180° C. for ≧10 seconds) during mounting semiconductor chips, the material enters the aforementioned portions as thermoplastic resin does. Thereafter, through post-curing under the conditions, for example, about 170° C. for about three hours, the semi-cured material is completely cured, to thereby provide the cured material with optimum characteristics for serving as an under-filling material. If heat is applied to the flexible printed wiring board again, the filling material is not softened and remains stable, which is preferred.

The metal layer 15 is formed of a metal sheet having good thermal conductivity, and examples of the material of the metal sheet include copper, iron, aluminum, zinc, tin, magnesium, titanium, brass, and phosphor bronze. The metal layer 15 has been adhered to the surface of the wiring pattern 12 via the insulating adhesion layer 14. Among these materials, copper foil, aluminum foil, etc. are preferably employed. When copper foil or aluminum foil is used, a protective layer (e.g., tin-plate layer) is preferably formed on the surface of the metal foil.

In Embodiment 1, the insulating adhesion layer 14 and the metal layer 15 have been patterned in the same form, and these layers cover a portion of the wiring pattern 12 other than inner leads 21, input outer leads 22, and output outer leads 23. Notably, in Embodiment 1, a solder layer which has been employed in conventional film carrier tape is not employed, and instead, the insulating adhesion layer 14 is provided. The metal layer 15 is adhered to the insulating adhesion layer 14.

The flexible printed wiring board 10 as described above may be produced generally through a process as conventionally employed. However, in an alternative manner, the insulating adhesion layer 14 and the metal layer 15 may be formed through a similar photolithographic process after formation of the wiring pattern 12. In a still further alternative manner, a laminate of the insulating adhesion layer 14 and the metal layer 15 having a specific shape may be stacked on the wiring pattern 12. The laminate of the insulating adhesion layer 14 and the metal layer 15 having a specific shape may be formed through punching and etching of the metal layer.

Since the flexible printed wiring board 10 has been produced through adhering the metal layer 15 via the insulating adhesion layer 14 formed of NCF without provision of a solder resist layer, excellent heat dissipating performance can be attained from a simple structure. In addition, the absence of a solder resist layer realizes a decrease in thickness of the produced wiring board, leading to excellent bending performance. When a thermosetting NCF is employed as the insulating adhesion layer 14, warpage of the wiring board, which would otherwise be caused by shrinkage stress of NCF, can be prevented by the presence of the metal layer 15 adhered to the insulating adhesion layer.

Needless to say, in addition to the metal layer 15, another metal layer which can dissipate heat may be provided on the backside of the insulating substrate 11.

FIG. 2 shows an exemplary semiconductor device in which semiconductor chips and other parts are mounted on such a flexible printed wiring board 10.

In a semiconductor device 1, a semiconductor chip 31 is mounted on inner leads 21 of the flexible printed wiring board 10. A substrate 32 serving as an input member is connected to an input outer lead 22, and an LCD panel 33 serving as an output member is connected to an output outer lead 23.

The semiconductor chip 31 is connected to the inner leads 21 via a bump 34. The substrate 32 is connected to the input outer lead 22 via an ACF (anisotropic conductive film) 35, and the LCD panel 33 is connected to the output outer lead 23 via an ACF 36.

In the semiconductor device 1 employing the flexible printed wiring board 10, the metal layer 15 is disposed in the vicinity of the semiconductor chip 31. Thus, the heat generated by the semiconductor chip 31 is transferred to the metal layer 15 via the wiring pattern 12 and the insulating adhesion layer 14 and also through heat radiation, and the transferred heat is radiated from the metal layer 15. As a result, reliable operation of the semiconductor chip 31 is ensured.

### Embodiment 2

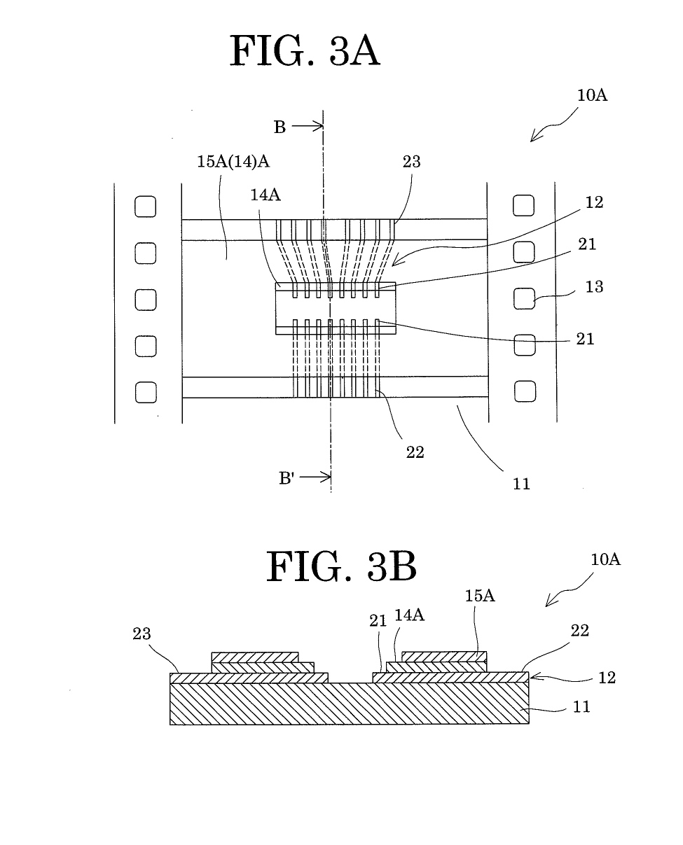

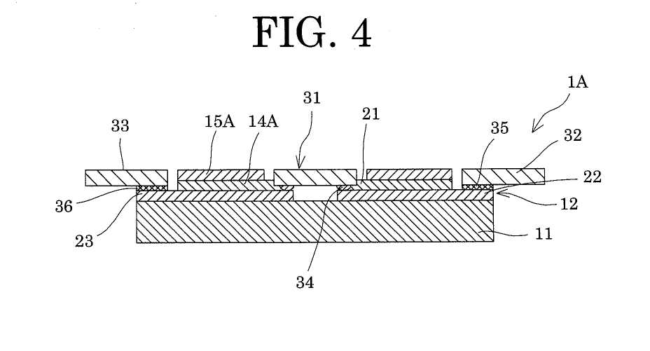

FIG. 3A is a schematic plan view of a flexible printed wiring board according to Embodiment 2 of the present invention; FIG. 3B is a cross-sectional view of the same; and FIG. 4 is a schematic cross-sectional view of a semiconductor device employing the flexible printed wiring board on which semiconductor chips and other parts have been mounted.

FIG. 3A shows a flexible printed wiring board 10A of Embodiment 2. In the wiring board, an insulating adhesion layer 14A and a metal layer 15A cover an area of a wiring pattern 12 other than any of inner leads 21, input outer leads 22, and output outer leads 23. Differing from Embodiment 1, each edge of the insulating adhesion layer 14A on the side of the inner lead 21 protrudes from a corresponding edge of the metal layer 15A. Other elements of the wiring board of Embodiment 2 are generally the same as employed in Embodiment 1 and are denoted by the same reference numerals, and the overlapping descriptions are omitted.

As described hereinbelow, each edge of the insulating adhesion layer 14A on the side of the inner lead 21 is preferably designed such that the edge comes into contact with a corresponding edge of the semiconductor chip 31 during mounting of the semiconductor chip 31 on the inner leads 21, whereby an exposed portion of each inner lead 21 is covered with the insulating adhesion layer. Through employment of the structure, an exposed portion of each inner lead 21 is covered with the insulating adhesion layer after mounting of the semiconductor chip 31, and the durability of the inner leads is enhanced as compared with the case of Embodiment 1.

FIG. 4 shows an exemplary semiconductor device in which semiconductor chips and other parts are mounted on such a flexible printed wiring board 10A.

In a semiconductor device 1A, a semiconductor chip 31 is mounted on inner leads 21 of a flexible printed wiring board 10A. A substrate 32 serving as an input member is connected to an input outer lead 22, and an LCD panel 33 serving as an output member is connected to an output outer lead 23.

The edges of the mounted semiconductor chip 31 come into contact with the edges of the insulating adhesion layer 14A. Through employment of the structure, an exposed portion of each inner lead 21 is covered with the insulating adhesion layer after mounting of the semiconductor chip 31, and the durability of the inner leads can be effectively enhanced as compared with the case of Embodiment 1.

In the semiconductor device 1A employing the flexible printed wiring board 10A, the metal layer 15A is disposed in the vicinity of the semiconductor chip 31. Thus, the heat generated by the semiconductor chip 31 is transferred to the metal layer 15A via the wiring pattern 12 and the insulating adhesion layer 14A and also through heat radiation, and the transferred heat is radiated from the metal layer 15A. As a result, reliable operation of the semiconductor chip 31 is ensured. This feature is the same as described in Embodiment 1.

### Embodiment 3

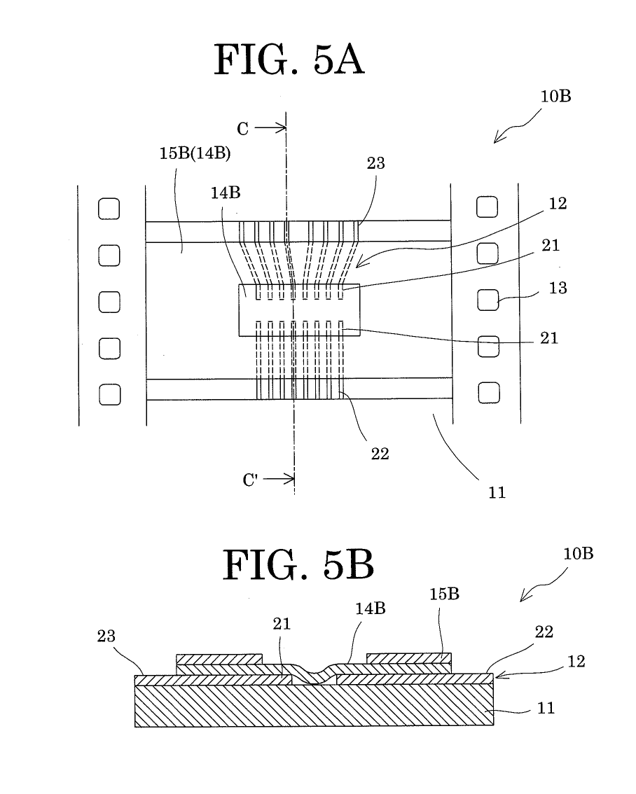

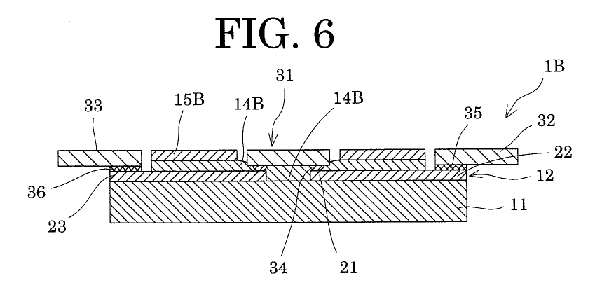

FIG. 5A is a schematic plan view of a flexible printed wiring board according to Embodiment 3 of the present invention; FIG. 5B is a cross-sectional view of the same; and FIG. 6 is a schematic cross-sectional view of a semiconductor device employing the flexible printed wiring board on which semiconductor chips and other parts have been mounted.

FIG. 5A shows a flexible printed wiring board 10B of Embodiment 3. In the wiring board, an insulating adhesion layer 14B and a metal layer 15B cover an area of a wiring pattern 12 other than any of input outer leads 22 and output outer leads 23. Differing from Embodiment 1, the insulating adhesion layer 14B covers the inner leads 21, and an area of the substrate between the edges of the opposing inner leads. Other elements of the wiring board of Embodiment 3 are generally the same as employed in Embodiment 1 and are denoted by the same reference numerals, and the overlapping descriptions are omitted. Similar to Embodiments 1 and 2, the metal layer 15B is provided such that the layer does not cover a space for mounting a semiconductor chip 31.

Since the space under the semiconductor chip 31 is filled with the insulating adhesion layer 14B, an under-filling material is not needed, which is advantageous.

FIG. 6 shows an exemplary semiconductor device in which semiconductor chips and other parts are mounted on such a flexible printed wiring board 10B.

In a semiconductor device 1B, a semiconductor chip 31 is mounted on inner leads 21 of a flexible printed wiring board 10B. A substrate 32 serving as an input member is connected to an input outer lead 22, and an LCD panel 33 serving as an output member is connected to an output outer lead 23.

The space under the mounted semiconductor chip 31 is filled with the insulating adhesion layer 14B. Thus, an exposed portion of the inner lead 21 is covered, and the space under the semiconductor chip 31 is filled with the insulating adhesion layer after mounting, whereby the durability of the leads can be more enhanced as compared with the cases of Embodiments 1 and 2.

In the semiconductor device 1B employing the flexible printed wiring board 10B, the metal layer 15B is disposed in the vicinity of the semiconductor chip 31. Thus, the heat generated by the semiconductor chip 31 is transferred to the metal layer 15B via the wiring pattern 12 and the insulating adhesion layer 14B and also through heat radiation, and the transferred heat is radiated from the metal layer 15B. As a result, reliable operation of the semiconductor chip 31 is ensured. This feature is the same as described in Embodiment 1.

### Embodiment 4

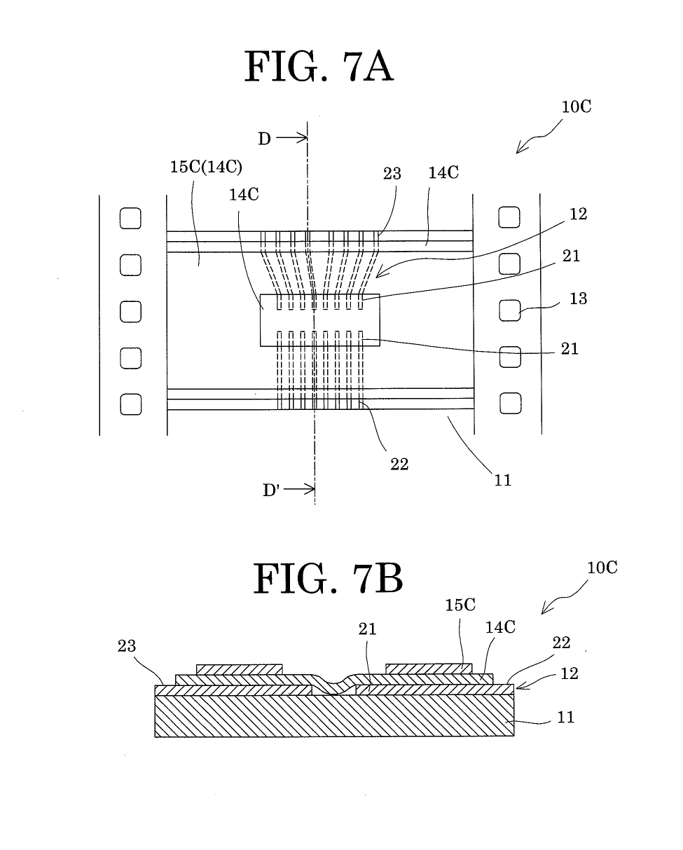

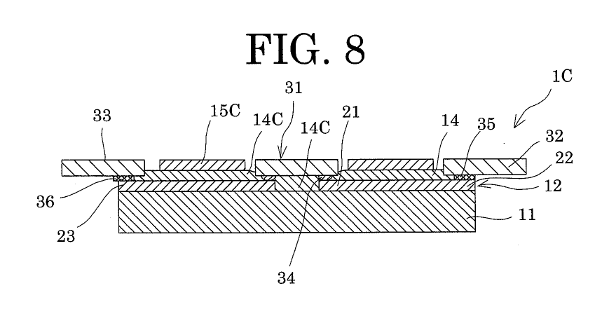

FIG. 7A is a schematic plan view of a flexible printed wiring board according to Embodiment 4 of the present invention; FIG. 7B is a cross-sectional view of the same; and FIG. 8 is a schematic cross-sectional view of a semiconductor device employing the flexible printed wiring board on which semiconductor chips and other parts have been mounted.

FIG. 7A shows a flexible printed wiring board 10C of Embodiment 4. In the wiring board, an insulating adhesion layer 14C and a metal layer 15C cover an area of a wiring pattern 12 other than any of input outer leads 22 and output outer leads 23. Differing from Embodiment 1, the insulating adhesion layer 14C covers the inner leads 21, and an area of the substrate between the edges of the opposing inner leads, and the edge of the insulating adhesion layer 14C on the side of the input outer lead 22 and that on the side of the output outer lead 23 protrude from corresponding edges of the metal layer 15C, respectively. Other elements of the wiring board of Embodiment 3 are generally the same as employed in Embodiment 1 and are denoted by the same reference numerals, and the overlapping descriptions are omitted. Similar to Embodiments 1 to 3, the metal layer 15C is provided such that the layer does not cover a space for mounting a semiconductor chip 31.

In Embodiment 4, the edge of the insulating adhesion layer 14C on the side of the input outer lead 22 and that on the side of the output outer lead 23 protrude from corresponding edges of the metal layer 15C, respectively. Therefore, ACF members for connecting the substrate 32 and the LCD panel 33 to the outer leads come into contact with the edges of the insulating adhesion layer 14C, respectively. Thus, the outer leads 22, 23 are covered with the insulating adhesion layer 14C and ACF members 35, 36, to thereby cover the exposed portions, whereby wire breakage at the exposed portions, which would otherwise be caused by stress concentration during bending can be prevented, resulting in enhancement in durability.

FIG. 8 shows an exemplary semiconductor device in which semiconductor chips and other parts are mounted on such a flexible printed wiring board 10C.

In a semiconductor device 1C, a semiconductor chip 31 is mounted on inner leads 21 of a flexible printed wiring board 10C. A substrate 32 serving as an input member is connected to an input outer lead 22, and an LCD panel 33 serving as an output member is connected to an output outer lead 23.

In the semiconductor device, the outer leads 22, 23 are covered with the insulating adhesion layer 14C and ACF members 35, 36, to thereby cover the exposed portions. Therefore, wire breakage at the exposed portions, which would otherwise be caused by stress concentration during bending can be prevented, resulting in enhancement in durability.

Similar to Embodiment 3, the space under the mounted semiconductor chip 31 is filled with the insulating adhesion layer 14C. Thus, an exposed portion of the inner lead 21 is covered, and the space under the semiconductor chip 31 filled with the insulating adhesion layer after mounting, whereby the durability of the leads can be more enhanced as compared with the cases of Embodiments 1 and 2.

In the semiconductor device 1C employing the flexible printed wiring board 10C, the metal layer 15C is disposed in the vicinity of the semiconductor chip 31. Thus, the heat generated by the semiconductor chip 31 is transferred to the metal layer 15C via the wiring pattern 12 and the insulating adhesion layer 14C and also through heat radiation, and the transferred heat is radiated from the metal layer 15C. As a result, reliable operation of the semiconductor chip 31 is ensured. This feature is the same as described in Embodiment 1.

### EXAMPLES

The present invention will next be described in detail by way of examples, which should not be construed as limiting the invention thereto.

### Example 1

On a surface of a polyimide film (thickness: 35 μm) (Upilex, product of Ube Industries, Ltd.) serving as an insulating substrate, an Ni—Cr alloy layer (thickness: 250 Å) and a Cu layer thickness: 2,000 to 5,000 Å) were sequentially formed through sputtering. The Cu layer was further plated with copper, to thereby form a copper plate layer (thickness: 8 μm). The thus-produced laminated substrate was slit into pieces having a width of 48 mm. Each slit piece was punched by means of a metal mold, to thereby make sprocket holes (about 2 mm×about 2 mm) for a conveyance guide at intervals of 4.75 mm.

Subsequently, a resist liquid was applied to the surface of the copper plate layer of the laminated substrate to a thickness of 4 to 5 μm, and dried and cured by passing the substrate through a tunnel-shape heating furnace.

Then, the resist was irradiated with an UV ray through a photomask having a specific circuit wiring pattern, and a photoresist circuit was formed through alkali development. Subsequently, the exposed copper surface was etched with an etchant, and the remaining resist was removed with caustic soda, to thereby form a copper pattern of interest.

The copper pattern included 650 output outer leads (pitch: 60 μm length: 3 mm) and 96 input outer leads (pitch: 394 μm, length: 2.5 mm). A semiconductor chip to be mounted on inner leads had a longer side of 17 mm and a shorter side of 2 mm. The minimum pitch of the inner leads was adjusted to 38 μm, and that of wiring portion was adjusted to 30 μm. One COF substrate had a length of 28.5 mm (equivalent to 6 perforations).

On the copper pattern, an Sn plate layer (thickness: 0.3 μm) was formed by use of a commercial electroless plating tin plate solution, to thereby complete a wiring pattern. The product was employed as a COF substrate.

Then, an NCF (epoxy adhesive sheet A0006FX-10C, product of Nagase ChemteX Corporation) (thickness: 50 μm) was cut to pieces (width: 48 mm), and each piece was placed on a coarse surface of electrolytic copper foil (thickness: 35 μm). The piece was laminated to the copper foil under the following rolling conditions (roller temperature: 90° C., rolling pressure: 0.4 MPa, and rolling speed: 0.3 m/minute), to thereby form an NCF-coated copper foil. This product was punched by means of a metal mold (punch size: 17.5×2.5 mm), to thereby produce NCF-coated copper foil pieces each having outer dimensions of 40 mm×23 mm with hole sizes of 17.5×2.5 mm.

A PET base film was removed from the NCF surface of each piece, and the piece was temporally fixed onto a predetermined position of the aforementioned wiring pattern. By means of a laminator, the piece was thermally press-bonded to the wiring pattern under the following conditions (upper and lower rubber roller temperatures: 190° C., rolling pressure: 0.4 MPa, and rolling speed: 0.3 m/minute), and post-curing (175° C.×3 hours) was performed, to thereby thermally cure the NCF in a semi-cured state.

The copper foil surface was protected by forming an electroless plate layer (0.1 μm) by use of an electroless tin plating solution, to thereby produce a flexible printed wiring board having a structure similar to that of Embodiment 1 (FIGS. 1A, 1B).

### Example 2

In a manner similar to that of Example 1, a COF substrate was produced. Separately, an NCF as employed in Example 1 was cut into pieces (40 mm×23 mm), and each piece was placed on a predetermined position of the COF substrate. The piece was laminated to the substrate under the following conditions (roller temperature: 90° C., rolling pressure: 0.4 MPa, and rolling speed: 0.3 m/minute), to thereby form an NCF-coated copper foil piece.

Subsequently, electrolytic copper foil (thickness: 35 μm) was punched by means of a metal mold (punch size: 17.5×2.5 mm), to thereby produce copper foil pieces each having outer dimensions of 40 mm×23 mm with hole sizes of 17.5×2.5 mm.

A coarsened surface of the copper foil piece was temporally fixed onto a predetermined position of the NCF from which a PET base film had been removed. The surface of the copper foil piece was protected by another PET film (thickness: 75 μm). The copper foil piece was thermally press-bonded to the NCF by means of a laminator under the following conditions (upper and lower rubber roller temperatures: 190° C., rolling pressure: 0.4 MPa, and rolling speed: 0.3 m/minute), whereby the copper foil piece was press-bonded to the NCF in a semi-cured state.

The copper foil surface was protected by forming an electroless plate layer (0.1 μm) by use of an electroless tin plating solution, to thereby produce a flexible printed wiring board having a structure similar to that of Embodiment 3 (FIGS. 5A, 5B).

In the thus-produced flexible printed wiring board, the inner leads on which a semiconductor chip is to be mounted are covered with NCF in a semi-cured state. Thus, a semiconductor chip is positioned on the NCF having tackiness. Subsequently, a bump attached to the semiconductor chip and inner leads of the COF substrate are thermally press-bonded by means of an inner lead bonder under specified conditions (e.g., at 200° C. for 19.8 seconds). Through the procedure, the bump penetrates the NCF, whereby the semiconductor chip can readily bonded to the inner leads. Through post-curing (e.g., 175° C.×3 hours), the NCF is thoroughly cured, and the semiconductor chip connecting portion is protected by the thus-cured NCF serving as an under-filling material.

### Example 3

In a manner similar to that of Example 1, a COF substrate was produced. Separately, an NCF as employed in Example 1 was cut into pieces (40 mm×24.5 mm), and each piece was placed on a predetermined position of the COF substrate. The piece was laminated to the substrate under the following conditions (roller temperature: 90° C., rolling pressure: 0.4 MPa, and rolling speed: 0.3 m/minute), to thereby form an NCF-coated copper foil piece. In Example 3, the width of the portion of NCF exposed from the edge of each output outer lead was adjusted to 1.4 mm, and the width of the portion of NCF exposed from the edge of each input outer lead was adjusted to 2 mm.

Subsequently, electrolytic copper foil (thickness: 35 μm) was punched by means of a metal mold (punch size: 17.5×2.5 mm), to thereby produce copper foil pieces each having outer dimensions of 40 mm×23 mm with hole sizes of 17.5×2.5 mm.

A coarsened surface of the copper foil piece was temporally fixed onto a predetermined position of the NCF from which a PET base film had been removed. The surface of the copper foil piece was protected by another PET film (thickness: 75 μm). The copper foil piece was thermally press-bonded to the NCF by means of a laminator under the following conditions (upper and lower rubber roller temperatures: 190° C., rolling pressure: 0.4 MPa, and rolling speed: 0.3 m/minute), and post-curing (175° C.×3 hours) was performed, to thereby thermally cure the NCF in a semi-cured state.

The copper foil surface was protected by forming an electroless plate layer (0.1 μm) by use of an electroless tin plating solution, to thereby produce a flexible printed wiring board having a structure similar to that of Embodiment 4 (FIGS. 7A, 7B).

Similar to Example 2, in the thus-produced flexible printed wiring board, the inner leads on which a semiconductor chip is to be mounted are covered with NCF in a semi-cured state. Thus, a semiconductor chip is positioned on the NCF having tackiness. Subsequently, a bump attached to the semiconductor chip and inner leads of the COF substrate are thermally press-bonded by means of an inner lead bonder under conditions (e.g., at 200° C. for 20 seconds). Through the procedure, the bump penetrates the NCF, whereby the semiconductor chip can readily bonded to the inner leads. Through post-curing (e.g., 175° C.×3 hours), the NCF is thoroughly cured, and the semiconductor chip connecting portion is protected by the thus-cured NCF serving as an under-filling material.

ACF (AC-4251F-16, product of Hitachi Chemical Co., Ltd.) (width: 1.5 mm) was temporally press-bonded to the exposed portions of output outer leads (width: 1.4 mm) at 110° C. for 3 seconds at a pressure of 1.5 kg/cm². Then, an ITO-coated (2,500 Å) glass sheet (26 mm×76 mm×0.7 mm (thickness)) was placed on the ACF, and the glass sheet was thoroughly press-bonded at 180° C. for 19.8 seconds at a pressure of 2.5 kg/cm². The bonding tool employed had a width of 3 mm and a length of 110 mm and was made of Super Invar. The hot-press-bonder employed was Pulse Heat Bonder TC-125 (product of Nippon Avionics Co., Ltd.).

According to Example 4, the output outer leads and the glass substrate were bonded via the ACF. Since the ACF was in contact with the NCF for a width of 0.1 mm, no exposed portion was present on the outer leads. Therefore, application of an anti-moisture agent to the exposed portion is not required, which is advantageous.

### Comparative Example 1

A COF substrate was produced in a manner similar to that of Example 1.

A solder resist ink (SN9000, product of Hitachi Chemical Co., Ltd.) was applied to an area of the produced COF substrate other than the areas on which output outer leads and inner leads were formed, through printing by means of a screen printer. The resist-coated COF was thermally cured, to thereby form a solder resist layer having a thickness of 15 μm.

### Test Example

For simulating dissipation heat generated by a mounted semiconductor chip, a heating resistor (18 mm×2 mm) was mounted on inner leads of a COF substrate sample of Example 3 or Comparative Example 1.

A rectified current (0.12 A, 10 V) was caused to pass through the heating resistor, and the temperature of the resistor surface was measured every 5 minutes at a position 20 mm apart from the resistor by means of a radiation thermometer (IR-100, product of Custom).

As a result, in the case of the COF substrate of Comparative Example 1, having no heat-dissipating metal layer, the highest temperature during the monitoring period of 30 minutes reached 100.3° C. In contrast, in the case of the COF substrate of Example 3, which has a metal layer at a position about 1.4 mm apart from the heating resistor, the highest temperature during the monitoring period of 30 minutes reached 86.7° C. A possible mechanism of heat dissipation is that heat generated by the heating resistor is transferred to the metal layer via heat radiation, and the transferred heat is dissipated through the metal layer.

What is claimed is:

1. A flexible printed wiring board comprising:
an insulating substrate,
a wiring pattern formed of a conductor layer and provided on one surface of the insulating substrate,
an insulating adhesion layer, and
a metal layer,
wherein the wiring pattern includes inner leads for mounting a semiconductor chip and outer leads for input and output wire connection, and the metal layer is adhered to the wiring pattern via the insulating adhesion layer.

2. A flexible printed wiring board according to claim 1, wherein the insulating adhesion layer covers areas except for any of the inner leads and the outer leads, and the metal layer is provided in the vicinity of a semiconductor chip mounted on the inner leads.

3. A flexible printed wiring board according to claim 2, wherein the metal layer has an edge on the inner lead side which edge recedes from an edge on the inner lead side of the insulating adhesion layer, and the edge of the insulating adhesion layer protrudes from the edge of the metal layer.

4. A flexible printed wiring board according to claim 1, wherein the insulating adhesion layer covers the inner leads, an area of the substrate between edges of the opposing inner leads, and an area of the wiring pattern other than the outer leads, and the metal layer is provided on an area of the insulating adhesion layer other than any of an area thereof on the inner leads and an area thereof between the edges of the opposing inner leads.

5. A flexible printed wiring board according to claim 2, wherein the metal layer has an edge on the outer lead side which edge recedes from an edge on the outer lead side of the insulating adhesion layer, and the edge of the insulating adhesion layer protrudes from the edge of the metal layer, to thereby cover a part of a connection terminal of each outer lead.

6. A flexible printed wiring board according to claim 1, wherein the insulating adhesion layer is formed of NCF or NCP.

7. A flexible printed wiring board according to claim 1, wherein the insulating adhesion layer contains a thermosetting resin in a semi-cured state.

8. A flexible printed wiring board according to claim 1, which has no solder resist layer on the wiring pattern.

9. A semiconductor device comprising a semiconductor chip mounted on inner leads of a flexible printed wiring board as recited in claim 1, and input and output members connected to outer leads of the flexible printed wiring board.
